(19) United States
(12) Patent Application Publication
(10) Pub. No.: US 2008/0270056 A1
(43) Pub. Date: Oct. 30, 2008

(54) WAFER-LEVEL RELIABILITY YIELD ENHANCEMENT SYSTEM AND RELATED METHOD

(76) Inventors: Yun-Chi Yang, Hsinchu County (TW); Cheng-Li Lin, Taoyuan County (TW); Chia-Jen Kao, Hsin-Chu City (TW); Ju-Ping Chen, Hsinchu City (TW); Kuan-Cheng Su, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/740,916

(22) Filed: Apr. 26, 2007

(51) Int. Cl. H01L 21/66; G01N 37/00

(52) U.S. Cl. 702/81; 324/769

(57) ABSTRACT

A yield enhancement system has a fabrication line with semiconductor fabrication devices for fabricating a wafer, an inspection and measurement monitoring system coupled to the fabrication line for determining process data corresponding to semiconductor fabrication devices, and a post-process testing line coupled to the fabrication line for performing in-line wafer-level testing. The post-process testing line includes a wafer acceptance tester, a yield monitor coupled to the wafer acceptance tester, and a wafer level reliability tester coupled to the wafer acceptance tester for estimating a life span of a device on the wafer.

### BACKGROUND OF THE INVENTION

1. Field of the Invention

The present invention relates to yield enhancement systems for semiconductor fabrication, and particularly to a wafer-level reliability yield enhancement system and related method.

2. Description of the Prior Art

Demand for high-performance, low-power, low-cost, mobile electronic products drives innovation in semiconductor fabrication as wafer manufacturers and foundries strive to meet those demands while maintaining high yield rate and device reliability. Ever decreasing device geometries result in tighter tolerances for each process step, be it lithography, etching, or oxidation. To increase yield, out-of-tolerance processes must be adjusted to within the allowable tolerances, and many inspection and monitoring systems are integrated into a yield enhancement system to provide engineers with data from each process, which can be correlated to defects found in electrical monitors, such as wafer acceptance testers or yield monitors.

Please refer to FIG. 1, which is a diagram of a yield enhancement system 100 according to the prior art. The yield enhancement system 100 comprises a fabrication line, a post-process testing line, inspection and measurement monitors 110 coupled to the fabrication line, and electrical monitors 120 coupled to the post-process testing line and the inspection and measurement monitors 110. The fabrication line comprises a lithographer (lithography) 111, an etcher (etching) 112, a thin film diffuser (thin film) 113, and an oxidizer (oxidation) 114. The post-process testing line comprises a wafer acceptance tester (WAT) 121 and a yield monitor 122 coupled to the WAT 121. In practice, coupling can be accomplished through a local area network (LAN).

In general, beyond data gathered from the inspection and measurement monitors 110 and the electrical monitors 120, device reliability data is also taken. For example, the device reliability data can be time-dependent dielectric breakdown (TDDB) data, which estimates a life span of electronic devices. Traditionally, the device reliability data is not integrated into the yield enhancement system 100. Thus, the yield enhancement system 100 of the prior art is not able to provide a comprehensive correlation between device reliability and process variables. Further, data from the WAT 121 or the yield monitor 122 cannot inform the device reliability test nor can data from the device reliability test inform the WAT 121 or the yield monitor 122.

The prior art reliability test is an off-line test, and does not provide data for yield mapping. Thus, the reliability test of the prior art cannot correspond to abnormalities of in-line processes. Thus, reliability test results cannot be used for yield analysis.

### SUMMARY OF THE INVENTION

According to the present invention, a yield enhancement system comprises a fabrication line comprising a plurality of semiconductor fabrication devices for fabricating a wafer, an inspection and measurement monitoring system coupled to the fabrication line for determining process data corresponding to the plurality of semiconductor fabrication devices, and a post-process testing line coupled to the fabrication line for performing in-line wafer-level testing. The post-process testing line comprises a wafer acceptance tester, a yield monitor coupled to the wafer acceptance tester, and a wafer level reliability tester coupled to the wafer acceptance tester for estimating a life span of a device on the wafer.

According to the present invention, a method of performing yield enhancement in a semiconductor fabrication process comprises obtaining reliability data, transforming the reliability data into a wafer mapping, determining a bad die location from the wafer mapping, and correlating the bad die location with a data source.

According to the present invention, a method of checking a complimentary metal oxide semiconductor (CMOS) device characteristic through an in-line wafer level reliability test comprises providing a semiconductor wafer comprising a CMOS device, utilizing an in-line wafer level reliability tester to apply a supply power to an input terminal of the CMOS device and to a power terminal of the CMOS device, and estimating a life span of the CMOS device according to an output of the CMOS device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a yield enhancement system according to the prior art.

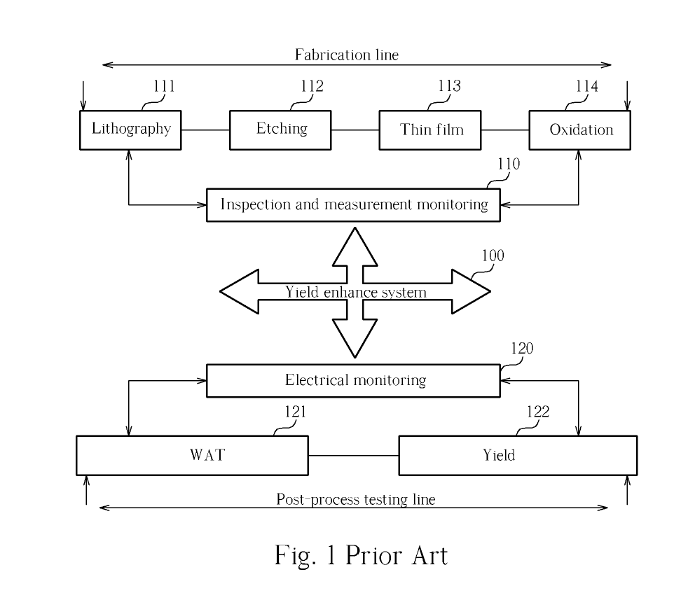

FIG. 2 is a diagram of a yield enhancement system according to the present invention.

FIG. 3 is a detailed diagram of the yield enhancement system of FIG. 2.

FIG. 4 is a flowchart of a method of performing yield enhancement in the yield enhancement system according to the present invention.

FIG. 5 is a flowchart of a method of checking a CMOS device characteristic through an in-line wafer level reliability test according to the present invention.

### DETAILED DESCRIPTION

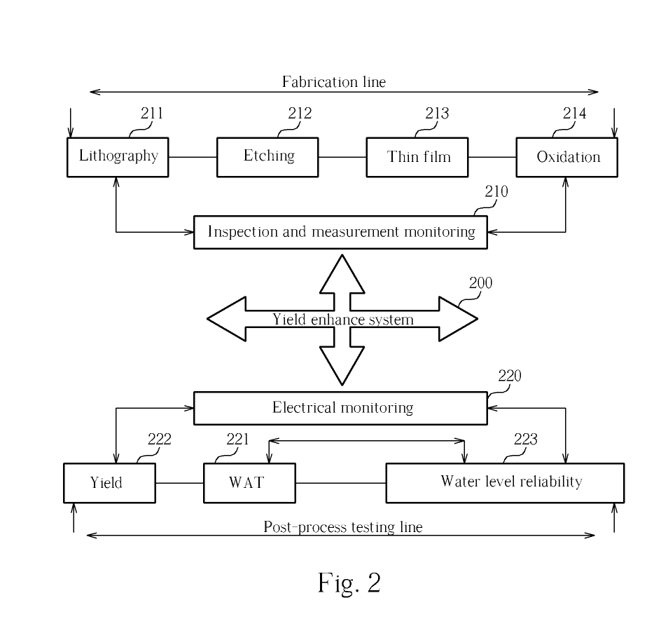

Please refer to FIG. 2, which is a diagram of a yield enhancement system 200 according to the present invention. The yield enhancement system 200 comprises a fabrication line, an inspection and measurement monitoring system 210, and a post-process testing line. The fabrication line comprises a plurality of semiconductor fabrication devices for fabricating a wafer. The inspection and measurement monitoring system 210 is coupled to the fabrication line for determining process data corresponding to the plurality of semiconductor fabrication devices. The post-process testing line is coupled to the fabrication line for performing in-line wafer-level testing, and comprises a wafer acceptance tester (WAT) 221, a yield monitor 222 coupled to the wafer acceptance tester 221, and a wafer level reliability tester 223 coupled to the wafer acceptance tester 221 for estimating a life span of a device on the wafer.

In FIG. 2, the plurality of semiconductor fabrication devices can comprise a lithographer, an etcher coupled to the lithographer, a thin film diffuser coupled to the etcher, and an oxidizer coupled to the thin film diffuser. The inspection and measurement monitoring system 210 can comprise an after developer/etching/deposition (AD/El) inspector and an image capture device.

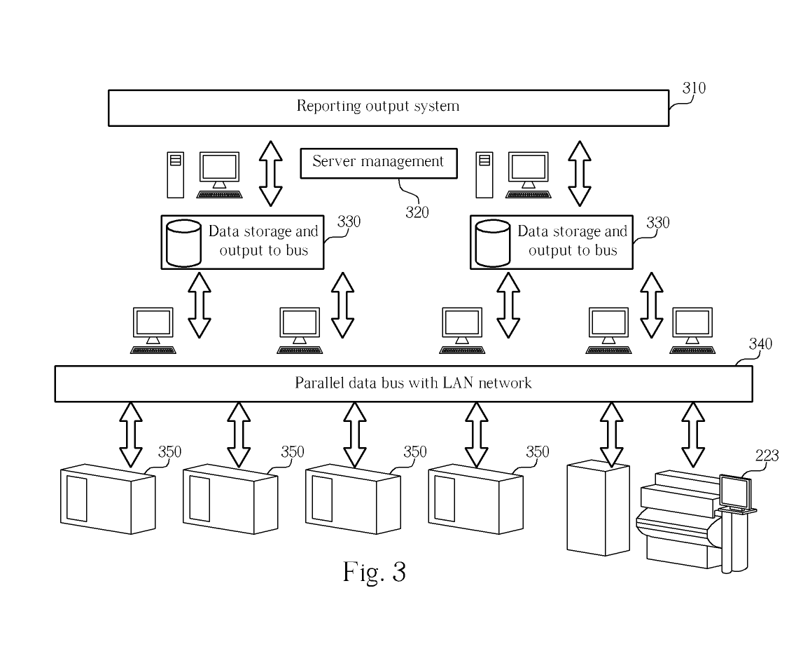

Please refer to FIG. 3, which is a detailed diagram of the yield enhancement system 200 shown in FIG. 2. A plurality of measurement and monitoring devices 350, i.e. the inspection and measurement monitoring system 210 and the post-process testing line of FIG. 2, and the wafer level reliability tester 223 of FIG. 2 are coupled through a parallel data bus 340. A plurality of data storage modules 330 are also coupled to the plurality of measurement and monitoring devices 350 and the wafer level reliability tester 223 through the parallel data bus 340. A server management system 320 is coupled to a reporting output system 310 and to the plurality of data storage modules 330.

The wafer level reliability tester 223 is capable of performing a time-dependent dielectric breakdown (TDDB) test for determining the life span of the CMOS device on the wafer. Because the wafer level reliability tester 223 is coupled to the WAT 221 through the parallel data bus 340, the wafer level reliability tester 223 can receive data from the WAT 221, such as WAT_Vfb information used for calculating interface defect density, automatically through the parallel data bus 340, which speeds up process debugging. Thus, TDDB_SILC can be automatically monitored and interface defect density can be calculated immediately. Further, wafer level reliability data obtained from the wafer level reliability tester 223 can be converted to a wafer map, which increases yield enhancement through faster process debug from in-line monitoring to device reliability.

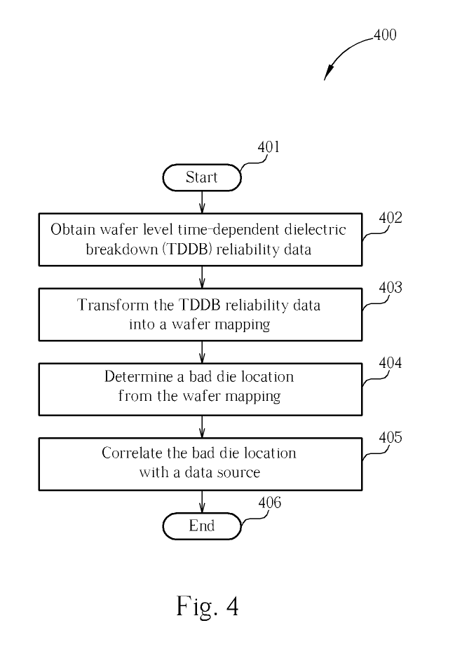

Please refer to FIG. 4, which is a flowchart of a method 400 for performing yield enhancement in the yield enhancement system according to the present invention. The method 400 comprises the following steps:

Step 401: Start.

Step 402: Obtain wafer level time-dependent dielectric breakdown (TDDB) reliability data.

Step 403: Transform the TDDB reliability data into a wafer mapping.

Step 404: Determine a bad die location from the wafer mapping.

Step 405: Correlate the bad die location with a data source.

Step 406: End.

In the method 400 described above, correlating the bad die location with the data source (Step 405) can comprise correlating the bad die location with in-line inspection data, correlating the bad die location with wafer yield mapping data, or correlating the bad die location with etch rate data.

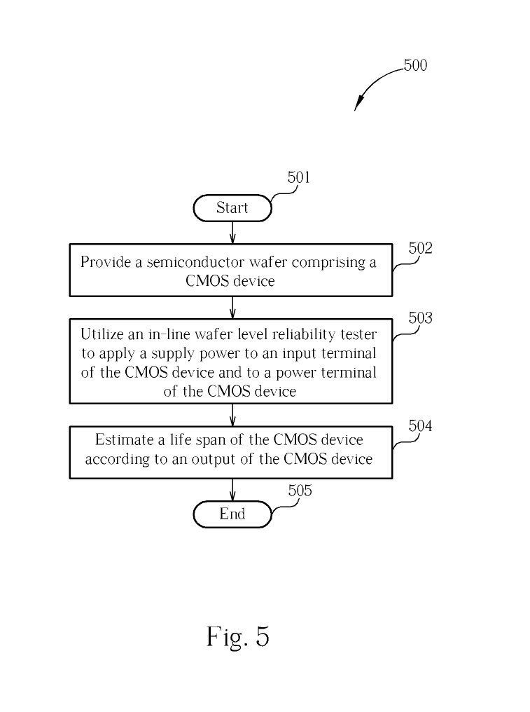

Please refer to FIG. 5, which is a flowchart of a method 500 for checking a complimentary metal oxide semiconductor (CMOS) device characteristic through an in-line wafer level reliability test according to the present invention. The method 500 comprises the following steps:

Step 501: Start.

Step 502: Provide a semiconductor wafer comprising a CMOS device.

Step 503: Utilize an in-line wafer level reliability tester to apply a supply power to an input terminal of the CMOS device and to a power terminal of the CMOS device.

Step 504: Estimate a life span of the CMOS device according to an output of the CMOS device.

Step 505: End.

In the method 500, providing the semiconductor wafer comprising the CMOS device (Step 502) can comprise providing a semiconductor wafer comprising a CMOS inverter. Utilizing the in-line wafer level reliability tester to apply the supply power to the input terminal of the CMOS device and to the power terminal of the CMOS device (Step 503) comprises utilizing the in-line wafer level reliability tester to apply a supply voltage or a supply current to the input terminal of the CMOS device and to the power terminal of the CMOS device. Estimating the life span of the CMOS device according to the output of the CMOS device (Step 504) comprises estimating a time-dependent dielectric breakdown (TDDB) lifetime of the CMOS device according to the output of the CMOS device. The output of the CMOS device can comprise a current output of the CMOS device or a voltage output of the CMOS device.

In conclusion, by integrating the wafer level reliability tester 223 into the yield enhancement system through the parallel data bus 340, the WAT_Vfb data from the WAT 221 can be fed forward to the wafer level reliability tester 223 to inform the TDDB test automatically, thereby allowing for automatic monitoring of TDDB_SILC, and immediate calculation of interface defect density. Further, the wafer level reliability data obtained from the wafer level reliability tester 223 can be converted into a wafer map format for correlation with results from the process measurement and monitoring devices along with the yield monitor and the WAT. Real-time analysis according to the wafer level testing improves response efficiency from monthly data feedback to daily feedback, and changes indirect wafer mapping correlation to direct wafer mapping results. This allows for a more comprehensive yield enhancement effect, and also greatly increases efficiency of reliability test processes.

Those skilled in the art will readily observe that numerous modifications and alterations of the device and method may be made while retaining the teachings of the invention. Accordingly, the above disclosure should be construed as limited only by the metes and bounds of the appended claims.

1. A yield enhancement system comprising:
a fabrication line comprising a plurality of semiconductor fabrication devices for fabricating a wafer;
an inspection and measurement monitoring system coupled to the fabrication line for determining process data corresponding to the plurality of semiconductor fabrication devices; and
a post-process testing line coupled to the fabrication line for performing in-line wafer-level testing comprising:
a wafer acceptance tester;
a yield monitor coupled to the wafer acceptance tester; and
a wafer level reliability tester coupled to the wafer acceptance tester for estimating a life span of a device on the wafer;
wherein the wafer level reliability tester estimates the life span of the device on the wafer through an in-line operation.

2. The yield enhancement system of claim 1, wherein the plurality of semiconductor fabrication devices comprises:
a lithographer;
an etcher coupled to the lithographer;
a thin film diffuser coupled to the etcher; and
an oxidizer coupled to the thin film diffuser.

3. The yield enhancement system of claim 1, wherein the inspection and measurement monitoring system comprises:
an after developer/etching/deposition (AD/EI) inspector; and
an image capture device.

4. The yield enhancement system of claim 1, wherein the wafer level reliability tester comprises a time-dependent dielectric breakdown (TDDB) tester.

5. The yield enhancement system of claim 1, wherein the wafer acceptance tester is coupled to the wafer level reliability tester through a local area network (LAN).

6. A method of performing yield enhancement in a semiconductor fabrication process comprising:
obtaining reliability data through an in-line operation;
transforming the reliability data into a wafer mapping;
determining a bad die location from the wafer mapping; and
correlating the bad die location with a data source.

7. The method of claim 6, wherein correlating the bad die location with the data source comprises correlating the bad die location with in-line inspection data.

8. The method of claim 6, wherein correlating the bad die location with the data source comprises correlating the bad die location with wafer yield mapping data.

9. The method of claim 6, wherein correlating the bad die location with the data source comprises correlating the bad die location with etch rate data.

10. The method of claim 6, wherein obtaining the reliability data comprises obtaining wafer level time-dependent dielectric breakdown (TDDB) data.

11. A method of checking a complimentary metal oxide semiconductor (CMOS) device characteristic through an in-line wafer level reliability test comprising:
providing a semiconductor wafer comprising a CMOS device;
utilizing an in-line wafer level reliability tester to apply a supply power to an input terminal of the CMOS device and to a power terminal of the CMOS device through an in-line operation; and
estimating a life span of the CMOS device according to an output of the CMOS device.

12. The method of claim 11, wherein providing the semiconductor wafer comprising the CMOS device comprises providing a semiconductor wafer comprising a CMOS inverter.

13. The method of claim 11, wherein utilizing the in-line wafer level reliability tester to apply the supply power to the input terminal of the CMOS device and to the power terminal of the CMOS device comprises utilizing the in-line wafer level reliability tester to apply a supply voltage to the input terminal of the CMOS device and to the power terminal of the CMOS device.

14. The method of claim 11, wherein estimating the life span of the CMOS device according to the output of the CMOS device comprises estimating a time-dependent dielectric breakdown (TDDB) lifetime of the CMOS device according to the output of the CMOS device.

15. The method of claim 11, wherein estimating the life span of the CMOS device according to the output of the CMOS device comprises estimating the life span of the CMOS device according to a current output of the CMOS device.
